(19) United States
(12) Patent Application Publication
(10) Pub. No.: US 2010/0212739 A1
(43) Pub. Date: Aug. 26, 2010

(54) SOLAR CELL AND METHOD OF MANUFACTURING THE SAME

(76) Inventors: Youngjoo EO, Seoul (KR); Sehwon AHN, Seoul (KR); Seungyoon LEE, Seoul (KR)

Correspondence Address: BIRCH STEWART KOLASCH & BIRCH, PO BOX 747, FALLS CHURCH, VA, 22040-0747, US

(21) Appl. No.: 12/688,554

(22) Filed: Jan. 15, 2010

(30) Foreign Application Priority Data
Feb. 25, 2009 (KR) 10-2009-0015781

(51) Int. Cl. H01L 31/00

(52) U.S. Cl. 136/258

(57) ABSTRACT

A solar cell and a method of manufacturing the same are discussed. The solar cell includes an amorphous silicon layer, and a density of Si—Si bonds in the amorphous silicon layer is 7.48×10²²/cm³ to 9.4×10²²/cm³. The method includes forming an electrode on a substrate and depositing amorphous silicon on the substrate in an atmosphere in which a ratio of an amount of hydrogen (H₂) gas to an amount of silane (SiH₄) gas is 15:1 to 30:1 to form an amorphous silicon layer on the substrate.

This application claims the benefit of Korean Patent Application No. 10-2009-0015781 filed on Feb. 25, 2009, the entire contents of which is incorporated herein by reference for all purposes as if fully set forth herein.

### BACKGROUND OF THE INVENTION

1. Field of the Invention

Embodiments of the invention relate to a solar cell and a method of manufacturing the same.

2. Discussion of the Related Art

A solar cell is an element capable of converting light energy into electrical energy. The solar cell may be mainly classified into a silicon-based solar cell, a compound-based solar cell, and an organic-based solar cell depending on a material used. The silicon-based solar cell may be classified into a crystalline silicon (c-Si) solar cell and an amorphous silicon (a-Si) solar cell depending on a phase of a semiconductor. Further, the solar cell may be classified into a bulk type solar cell and a thin film type solar cell depending on a thickness of a semiconductor.

A general operation of the solar cell is as follows. If light coming from the outside is incident on the solar cell, electron-hole pairs are formed inside a silicon layer of the solar cell. Electrons move to an n-type silicon layer and holes move to a p-type silicon layer by an electric field generated in a p-n junction of the solar cell. Hence, electric power is produced.

While an a-Si solar cell using amorphous silicon may be manufactured as a thin solar cell, a low efficiency is obtained from the a-Si solar cell.

### SUMMARY OF THE INVENTION

In one aspect, there is a solar cell including a first electrode, a second electrode; and an amorphous silicon layer disposed between the first electrode and the second electrode, an amorphous silicon layer, wherein a density of Si—Si bonds in the amorphous silicon layer is 7.48×10²²/cm³ to 9.4×10²²/cm³.

The density of Si—Si bonds in the amorphous silicon layer may be 7.8×10²²/cm³ to 9.0×10²²/cm³.

The density of Si—Si bonds in the amorphous silicon layer may be greater than a density of Si—H bonds in the amorphous silicon layer.

The density of Si—H bonds in the amorphous silicon layer may be greater than a density of dangling bonds.

In another aspect, there is a solar cell including a substrate, a first electrode on the substrate, a second electrode, and a photoelectric conversion unit disposed between the first electrode and the second electrode, the photoelectric conversion unit including an amorphous silicon layer, wherein a density of Si—Si bonds in the amorphous silicon layer is 7.48×10²²/cm³ to 9.4×10²²/cm³.

The density of Si—Si bonds in the amorphous silicon layer may be 7.8×10²²/cm³ to 9.0×10²²/cm³.

In another aspect, there is a solar cell including a substrate, a first electrode on the substrate, a second electrode, and a photoelectric conversion unit disposed between the first electrode and the second electrode, the photoelectric conversion unit including a p-type semiconductor layer formed of amorphous silicon, an intrinsic (i-type) semiconductor layer formed of amorphous silicon, and an n-type semiconductor layer formed of amorphous silicon, wherein a density of Si—Si bonds in at least one of the p-type semiconductor layer, the i-type semiconductor layer, and the n-type semiconductor layer is 7.48×10²²/cm³ to 9.4×10²²/cm³.

The density of Si—Si bonds in at least one of the p-type semiconductor layer, the i-type semiconductor layer, and the n-type semiconductor layer may be 7.8×10²²/cm³ to 9.0×10²²/cm³.

A density of Si—Si bonds in at least one of the p-type semiconductor layer and the n-type semiconductor layer may be less than a density of Si—Si bonds in the i-type semiconductor layer.

In another aspect, there is a solar cell including a substrate, a first electrode on the substrate, a second electrode, a first photoelectric conversion unit disposed between the first electrode and the second electrode, the first photoelectric conversion unit including a first intrinsic (i-type) semiconductor layer formed of amorphous silicon, a density of Si—Si bonds in the first i-type semiconductor layer being 7.48×10²²/cm³ to 9.4×10²²/cm³, and a second photoelectric conversion unit disposed between the first photoelectric conversion unit and the second electrode, the second photoelectric conversion unit including a second i-type semiconductor layer formed of microcrystalline silicon.

The density of Si—Si bonds in the first i-type semiconductor layer may be 7.8×10²²/cm³ to 9.0×10²²/cm³.

The first photoelectric conversion unit may include a first p-type semiconductor layer formed of amorphous silicon and a first n-type semiconductor layer formed of amorphous silicon. The second photoelectric conversion unit may include a second p-type semiconductor layer formed of microcrystalline silicon and a second n-type semiconductor layer formed of microcrystalline silicon.

A density of Si—Si bonds in at least one of the first p-type semiconductor layer and the first n-type semiconductor layer may be less than the density of Si—Si bonds in the first i-type semiconductor layer.

A thickness of the second i-type semiconductor layer may be greater than a thickness of the first i-type semiconductor layer.

The solar cell may further include an interlayer disposed between the first photoelectric conversion unit and the second photoelectric conversion unit.

In another aspect, there is a solar cell including a substrate, a first electrode on the substrate, a second electrode, a first photoelectric conversion unit disposed between the first electrode and the second electrode, the first photoelectric conversion unit including a first intrinsic (i-type) semiconductor layer formed of amorphous silicon, a second photoelectric conversion unit disposed between the first photoelectric conversion unit and the second electrode, the second photoelectric conversion unit including a second i-type semiconductor layer formed of amorphous silicon, and a third photoelectric conversion unit disposed between the second photoelectric conversion unit and the second electrode, the third photoelectric conversion unit including a third i-type semiconductor layer formed of microcrystalline silicon, wherein a density of Si—Si bonds in at least one of the first i-type semiconductor layer and the second i-type semiconductor layer is 7.48×10²²/cm³ to 9.4×10²²/cm³.

The density of Si—Si bonds in at least one of the first i-type semiconductor layer and the second i-type semiconductor layer may be 7.8×10²²/cm³ to 9.0×10²²/cm³.

The first photoelectric conversion unit may include a first p-type semiconductor layer formed of amorphous silicon and a first n-type semiconductor layer formed of amorphous silicon. The second photoelectric conversion unit may include a second p-type semiconductor layer formed of amorphous silicon and a second n-type semiconductor layer formed of amorphous silicon. The third photoelectric conversion unit may include a third p-type semiconductor layer formed of microcrystalline silicon and a third n-type semiconductor layer formed of microcrystalline silicon.

A density of Si—Si bonds in at least one of the first p-type semiconductor layer, the first n-type semiconductor layer, the second p-type semiconductor layer, and the second n-type semiconductor layer may be less than the density of Si—Si bonds in each of the first i-type semiconductor layer and the second i-type semiconductor layer.

In another aspect, there is a method of manufacturing a solar cell including forming an electrode on a substrate and depositing amorphous silicon on the substrate in an atmosphere in which a ratio of an amount of hydrogen (H₂) gas to an amount of silane (SiH₄) gas is 15:1 to 30:1 to form an amorphous silicon layer on the substrate.

The ratio of the amount of hydrogen (H₂) gas to the amount of silane (SiH₄) gas may be 17:1 to 28:1.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 illustrates an example structure of a solar cell according to an embodiment of the invention;

FIG. 2 illustrates a density of Si—Si bonds of an amorphous silicon layer;

FIG. 3 is a graph illustrating a density of Si—Si bonds depending on a ratio of an amount of hydrogen gas to an amount of silane gas;

FIG. 4 illustrates an example structure of a solar cell according to an embodiment of the invention;

FIGS. 5 to 7 illustrate an example structure of a solar cell including a plurality of photoelectric conversion units; and

FIGS. 8 to 11 illustrate an example structure of a solar cell according to an embodiment of the invention.

### DETAILED DESCRIPTION OF THE EMBODIMENTS

Reference will now be made in detail to embodiments of the invention, examples of which are illustrated in the accompanying drawings.

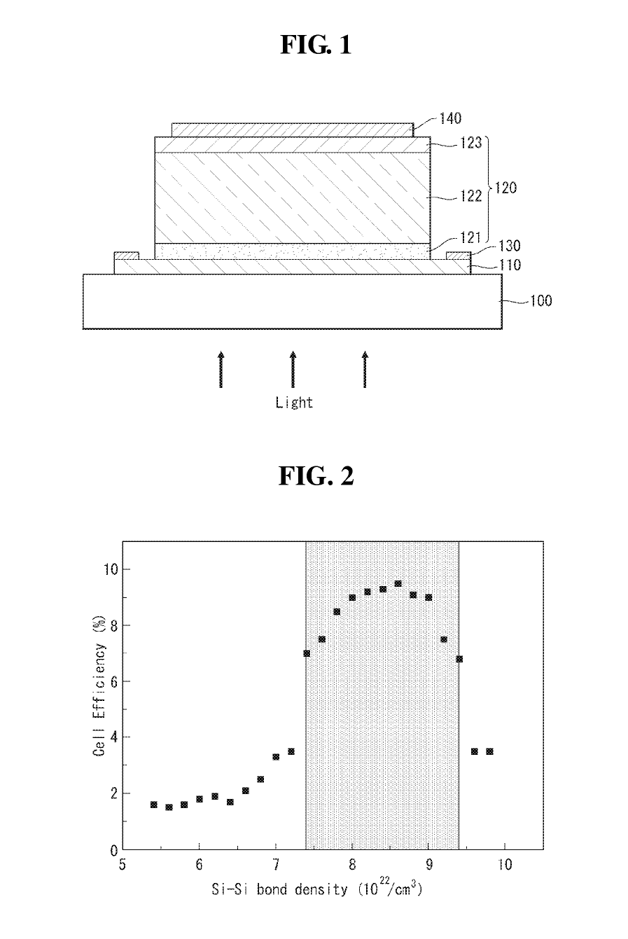

FIG. 1 illustrates an example structure of a solar cell according to an embodiment of the invention. As shown in FIG. 1, a solar cell according to an embodiment of the invention may include a substrate 100, a front electrode 110 on the substrate 100, a photoelectric conversion unit 120 and a grid electrode 130 on the front electrode 110, and a rear electrode 140 on the photoelectric conversion unit 120.

The photoelectric conversion unit 120 is positioned between the front electrode 110 and the rear electrode 140 to produce electric power using light coming from the outside. Further, the photoelectric conversion unit 120 may include an amorphous silicon layer.

The substrate 100 may provide a space for other functional layers. Further, the substrate 100 may be formed of a substantially transparent material, such as glass and plastic, so that light coming from the outside efficiently reaches the photoelectric conversion unit 120.

The front electrode 110 may be formed of a substantially transparent material with electrical conductivity so as to increase a transmittance of incident light. Thus, the front electrode 110 may be referred to as a transparent electrode. For example, the front electrode 110 may be formed of a material having high transmittance and high electrical conductivity, and/or selected from the group consisting of indium tin oxide (ITO), tin-based oxide (e.g., SnO₂), AgO, ZnO—Ga₂O₃ (or Al₂O₃), fluorine tin oxide (FTO), or a combination thereof, so that the front electrode 110 transmits most of incident light and a current flows in the front electrode 110. A specific resistance of the front electrode 110 may be approximately 10⁻¹¹ Ω·cm to 10⁻² Ω·cm. The front electrode 110 may be electrically connected to the photoelectric conversion unit 120. Hence, the front electrode 110 may collect carriers (e.g., holes) produced in the photoelectric conversion unit 120 by the incident light to output the carriers.

The grid electrode 130 may be positioned on the front electrode 110, on which the photoelectric conversion unit 120 is not formed, to prevent or reduce a reduction in photoelectric conversion efficiency of the photoelectric conversion unit 120

The rear electrode 140 may be formed of metal with high electrical conductivity so as to increase a recovery efficiency of electric power produced by the photoelectric conversion unit. Further, the rear electrode 140 may be electrically connected to the photoelectric conversion unit 120. Hence, the rear electrode 140 may collect carriers (e.g., electrons) produced by the incident light to output the carriers. The rear electrode 140 may be formed of a substantially transparent material, for example, ITO and ZnO similar to the front electrode 110.

The photoelectric conversion unit 120 may convert light from the outside into electrical energy. The photoelectric conversion unit 120 may be an amorphous silicon cell using amorphous silicon (a-Si), for example, hydrogenated amorphous silicon (a-Si:H).

The photoelectric conversion unit 120 may include a p-type semiconductor layer 121 formed of amorphous silicon, an n-type semiconductor layer 123 formed of amorphous silicon, and an intrinsic (referred to as an i-type) semiconductor layer 122 formed of amorphous silicon disposed between the p-type semiconductor layer 121 and the n-type semiconductor layer 123. In other words, the p-type semiconductor layer 121, the i-type semiconductor layer 122, and the n-type semiconductor layer 123 may be referred to as an amorphous silicon layer. Further, the p-type semiconductor layer 121 may be referred to as a p-type amorphous silicon layer, the i-type semiconductor layer 122 may be referred to as an i-type amorphous silicon layer, and the n-type semiconductor layer 123 may be referred to as an n-type amorphous silicon layer.

The p-type semiconductor layer 121 may be formed using a gas obtained by adding impurities of a group III element, such as boron (B), gallium (Ga), and/or indium (In), to a raw gas containing Si.

The i-type semiconductor layer 122 may reduce recombination of the carriers and may absorb light. The i-type semiconductor layer 122 may absorb incident light to produce carriers such as electrons and holes. The i-type semiconductor layer 122 may be formed of amorphous silicon (a-Si), for example, hydrogenated amorphous silicon (a-Si:H).

The n-type semiconductor layer 123 may be formed using a gas obtained by adding impurities of a group V element, such as phosphor (P), arsenic (As), and/or antimony (Sb), to a raw gas containing Si.

The photoelectric conversion unit 120 may be formed using a chemical vapor deposition (CVD) method, such as a plasma enhanced chemical vapor deposition (PECVD) method. Other methods may be used.

In the photoelectric conversion unit 120, the p-type semiconductor layer 121 and the n-type semiconductor layer 123 may form a p-n junction with the i-type semiconductor layer 122 interposed between the p-type semiconductor layer 121 and the n-type semiconductor layer 123. In other words, the i-type semiconductor layer 122 is positioned between the p-type semiconductor layer 121 (i.e., a p-type doped layer) and the n-type semiconductor layer 123 (i.e., an n-type doped layer).

In such a structure of the solar cell, if light is incident on the p-type semiconductor layer 121, a depletion region is formed in the i-type semiconductor layer 122 because of the p-type semiconductor layer 121 and the n-type semiconductor layer 123 each having a relatively high doping concentration to thereby generate an electric field. Electrons and holes generated in the i-type semiconductor layer 122 are separated by a contact potential difference through a photovoltaic effect and move in different directions. For example, the holes move to the front electrode 110 through the p-type semiconductor layer 121, and the electrons move to the rear electrode 140 through the n-type semiconductor layer 123. Hence, electric power is produced.

A solar cell applicable to the embodiment of the invention is not particularly limited, except that the solar cell includes an amorphous silicon layer. For example, although FIG. 1 shows a pin-type solar cell in which the p-type semiconductor layer 121, the i-type semiconductor layer 122, and the n-type semiconductor layer 123 may be positioned in the order named, a pin-pin type solar cell may be applied. The solar cell applicable to the embodiment of the invention may further include a microcrystalline silicon layer in addition to the amorphous silicon layer. In the solar cell applicable to the embodiment of the invention, a texturing process may be performed on the photoelectric conversion unit 120 so as to increase the photoelectric conversion efficiency.

FIG. 2 illustrates a density of Si—Si bonds in an amorphous silicon layer. More specifically, FIG. 2 is a graph illustrating a relationship between a density of Si—Si bonds in an amorphous silicon layer and an efficiency of a solar cell.

As shown in FIG. 2, a density of Si—Si bonds in an amorphous silicon layer may be adjusted to 7.48×10²²/cm³ to 9.4×10²²/cm³ so as to improve an efficiency of a solar cell including the amorphous silicon layer. Preferably, though not required, the density of Si—Si bonds in the amorphous silicon layer may be adjusted to 7.8×10²²/cm³ to 9.0×10²²/cm³.

When the density of Si—Si bonds in the amorphous silicon layer is approximately 7.48×10²²/cm³ to 7.6×10²²/cm³, the efficiency of the solar cell was a relatively high value of approximately 7.0% to 7.4%. When the density of Si—Si bonds in the amorphous silicon layer is approximately 9.2×10²²/cm³ to 9.4×10²²/cm³, the efficiency of the solar cell was a relatively high value of approximately 6.8% to 7.4%. Accordingly, considering this, it may be preferable, though not required, that the density of Si—Si bonds in the amorphous silicon layer is adjusted to 7.48×10²²/cm² to 9.4×10²²/cm³ so as to improve the efficiency of the solar cell including the amorphous silicon layer.

Further, when the density of Si—Si bonds in the amorphous silicon layer is approximately 7.8×10²²/cm³ to 9.0×10²²/cm³, the efficiency of the solar cell was a sufficiently high value of approximately 8.4% to 9.4%. Accordingly, considering this, it may be preferable, though not required, that the density of Si—Si bonds in the amorphous silicon layer is adjusted to 7.8×10²²/cm³ to 9.0×10²²/cm³ so as to further improve the efficiency of the solar cell including the amorphous silicon layer.

When the density of Si—Si bonds in the amorphous silicon layer is approximately 5.4×10²²/cm³ to 7.2×10²²/cm³, the efficiency of the solar cell was a relatively low value of approximately 1.5% to 3.5%. In this case, a small number of Si—Si bonds are formed in the amorphous silicon layer. In other words, there exist a large number of Si particles not forming Si—Si bonds in the amorphous silicon layer. The large number of Si particles not forming the Si—Si bonds form a large number of Si dangling bonds or Si—H bonds, and the large number of Si-dangling bonds or Si—H bonds may serve as defects in the amorphous silicon layer, such as recombination sites for the electron-hole pairs. Hence, the efficiency of the solar cell may be reduced.

When the density of Si—Si bonds in the amorphous silicon layer is equal to or greater than approximately 9.6×10²²/cm³, the efficiency of the solar cell was a very low value of approximately 3.5%. In this case, because a large number of Si—Si bonds are formed in the amorphous silicon layer, a small amount of hydrogen (H) particles may exist in the amorphous silicon layer. Hydrogen in the amorphous silicon layer is one of variables determining the efficiency of the solar cell. When a small amount of hydrogen exists in the amorphous silicon layer, the efficiency of the solar cell may be reduced.

A hydrogen content in the amorphous silicon is not excessively small and the number of Si—Si bonds have to be sufficient in consideration of the efficiency of the solar cell. Further, it is advantageous that the number of dangling bonds serving as a defect in the amorphous silicon is small.

Further, Si—H bonds may be formed or exist in the amorphous silicon, and Si dangling bonds may be formed or exist in the amorphous silicon. Accordingly, a density of Si—H bonds may be less than the density of Si—Si bonds and may be greater than a density of dangling bonds in the amorphous silicon in consideration of the efficiency of the solar cell.

Referring again to FIG. 1, when the photoelectric conversion unit 120 includes the p-type semiconductor layer 121 formed of amorphous silicon, the i-type semiconductor layer 122 formed of amorphous silicon, and the n-type semiconductor layer 123 formed of amorphous silicon, a density of Si—Si bonds in at least one of the p-type semiconductor layer 121, the i-type semiconductor layer 122, and the n-type semiconductor layer 123 may be approximately 7.48×10²²/cm³ to 9.4×10²²/cm³, preferably, approximately 7.8×10²²/cm³ to 9.0×10/cm³, though not required.

A density of Si—Si bonds in at least one of the p-type semiconductor layer 121 and the n-type semiconductor layer 123 may be less than a density of Si—Si bonds in the i-type semiconductor layer 122 considering that the p-type semiconductor layer 121 is doped with p-type impurities and the n-type semiconductor layer 123 is doped with n-type impurities.

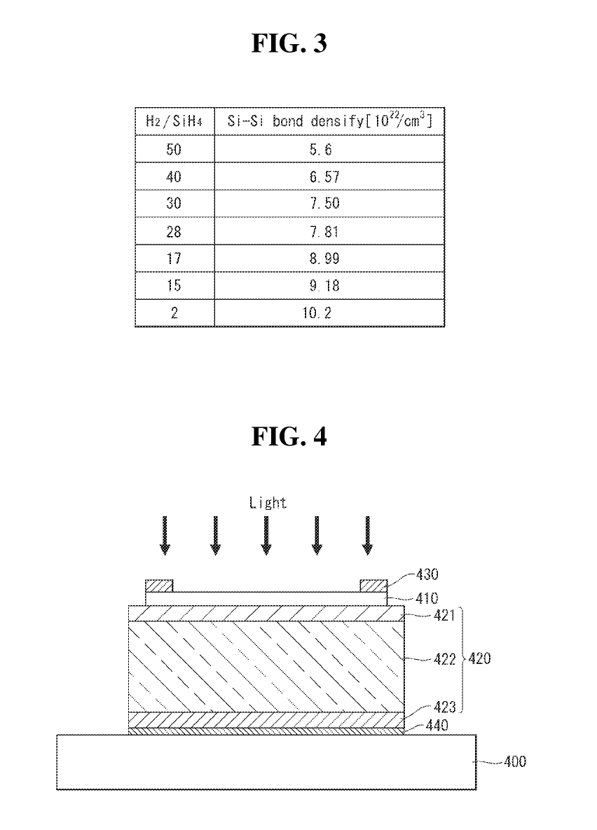

A method for manufacturing of the solar cell according to the embodiment of the invention is described below with reference to FIG. 3. FIG. 3 is a graph illustrating a density of Si—Si bonds depending on a ratio of an amount of hydrogen gas to an amount of silane gas.

In the solar cell according to the embodiment of the invention, the amorphous silicon layer may be formed using the PECVD method. In the PECVD method, hydrogen (H₂) gas and silane (SiH₄) gas may be used as source gases. A density of Si—Si bonds in the amorphous silicon layer may be adjusted by controlling a ratio of an amount of hydrogen (H₂) gas to an amount of silane (SiH₄) gas.

More specifically, a front electrode may be formed on a substrate and then silicon may be deposited on the front electrode to form a photoelectric conversion unit.

In a deposition of amorphous silicon, as shown in FIG. 3, when a ratio (H₂/SiH₄) of an amount of hydrogen (H₂) gas to an amount of silane gas is approximately 40:1 to 50:1, a density of Si—Si bonds in the deposited amorphous silicon layer is approximately 5.6×10²²/cm³ to 6.57×10²²/cm³. In this case, as shown in FIG. 2, the efficiency of the solar cell is reduced because of the excessively small density of Si—Si bonds in the amorphous silicon layer.

When the ratio (H₂/SiH₄) is approximately 2:1, the density of Si—Si bonds in the deposited amorphous silicon layer is approximately 10.2×10²²/cm³. In this case, as shown in FIG. 2, the efficiency of the solar cell is reduced because of the excessively large density of Si—Si bonds in the amorphous silicon layer.

On the other hand, when the ratio (H₂/SiH₄) is approximately 15:1 to 30:1, the density of Si—Si bonds in the deposited amorphous silicon layer is approximately 7.50×10²²/cm³ to 9.18×10²²/cm³. In this case, as shown in FIG. 2, the efficiency of the solar cell increases to a high level.

Further, when the ratio (H₂/SiH₄) is approximately 17:1 to 28:1, the density of Si—Si bonds in the deposited amorphous silicon layer is approximately 7.81×10²²/cm³ to 8.99×10²²/cm³. In this case, as shown in FIG. 2, the efficiency of the solar cell increases to a high level.

Considering the description of FIG. 3, when the ratio of the amount of hydrogen (H₂) gas to the amount of silane (SiH₄) gas is approximately 15:1 to 30:1 in a formation of the amorphous silicon layer, it may be preferable, though not required, that the amorphous silicon layer is deposited. More preferably, though not necessarily, the ratio of the amount of hydrogen (H₂) gas to the amount of silane (SiH₄) gas may be approximately 17:1 to 28:1.

Although FIG. 3 illustrates the PECVD method using the hydrogen (H₂) gas and the silane (SiH₄) gas as the source gases, any method capable of forming the amorphous silicon layer using the hydrogen (H₂) gas and the silane (SiH₄) gas may be used. For example, a photo-CVD method and a hot wire CVD method may be used.

FIG. 4 illustrates an example structure of a solar cell according to an embodiment of the invention. More specifically, FIG. 4 illustrates a solar cell including a plurality of amorphous silicon layers 421, 422, and 423. The solar cell shown in FIG. 4 may be referred to as an nip-type solar cell.

As shown in FIG. 4, a solar cell according to an embodiment of the invention may include a substrate 400, a rear electrode 440 on the substrate 400, a photoelectric conversion unit 420 on the rear electrode 440, a front electrode 410 on the photoelectric conversion unit 420, and a grid electrode 430 on the front electrode 410. In the following explanations, a further description of structures and components identical or equivalent to those illustrated in FIGS. 1 to 3 may be briefly made or may be entirely omitted.

In the solar cell having a structure shown in FIG. 4, the photoelectric conversion unit 420 may include an n-type semiconductor layer 423 formed of amorphous silicon, an i-type semiconductor layer 422 formed of amorphous silicon, and a p-type semiconductor layer 421 formed of amorphous silicon that are positioned on the substrate 400 in the order named.

Further, if light is incident on the front electrode 410 positioned opposite the substrate 400, the photoelectric conversion unit 420 may convert the incident light into electric power.

In such a structure shown in FIG. 4, because light is incident on the front electrode 410, the substrate 400 does not need to be transparent. Thus, the substrate 400 may be formed of metal in addition to glass and plastic.

Further, the solar cell according to the embodiment of the invention may further include a reflective layer capable of reflecting transmitted light from a rear surface of the substrate 400.

The solar cell according to the embodiment of the invention may include a pin-type amorphous silicon photoelectric conversion unit having at least a single-layered structure. The photoelectric conversion unit illustrated in FIGS. 1 to 4 may a pin-type amorphous silicon photoelectric conversion unit.

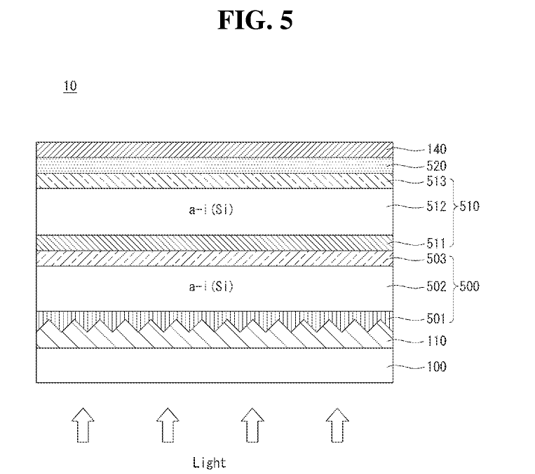

FIGS. 5 to 7 illustrate an example structure of a solar cell including a plurality of photoelectric conversion units. In the following explanations, a further description of structures and components identical or equivalent to those illustrated in FIGS. 1 to 4 may be briefly made or may be entirely omitted.

As shown in FIG. 5, a solar cell 10 according to an embodiment of the invention may include a first photoelectric conversion unit 500 and a second photoelectric conversion unit 510. The first photoelectric conversion unit 500 may include a first p-type semiconductor layer 501 formed of amorphous silicon, a first n-type semiconductor layer 503 formed of amorphous silicon, and a first i-type semiconductor layer 502 formed of amorphous silicon disposed between the first p-type semiconductor layer 501 and the first n-type semiconductor layer 503. The second photoelectric conversion unit 510 may include a second p-type semiconductor layer 511 formed of amorphous silicon, a second n-type semiconductor layer 513 formed of amorphous silicon, and a second i-type semiconductor layer 512 formed of amorphous silicon disposed between the second p-type semiconductor layer 511 and the second n-type semiconductor layer 513.

FIG. 5 shows the solar cell 10 including the two pin-type amorphous silicon photoelectric conversion units. Further, the solar cell 10 may include three or more pin-type amorphous silicon photoelectric conversion units in other embodiments.

The pin-type first and second amorphous silicon photoelectric conversion units 500 and 510 may increase a light absorptance and thus may improve the photoelectric conversion efficiency. In such a structure of the solar cell 10, the first i-type semiconductor layer 502 may mainly absorb light of a short wavelength band to produce electrons and holes. The second i-type semiconductor layer 512 may mainly absorb light of a long wavelength band to produce electrons and holes.

Because the solar cell 10 having a double junction structure absorbs the light of short wavelength band and the light of long wavelength band to produce carriers, the double junction solar cell 10 may have high efficiency.

A thickness of the second i-type semiconductor layer 512 may be greater than a thickness of the first i-type semiconductor layer 502, so as to sufficiently absorb the light of the long wavelength band.

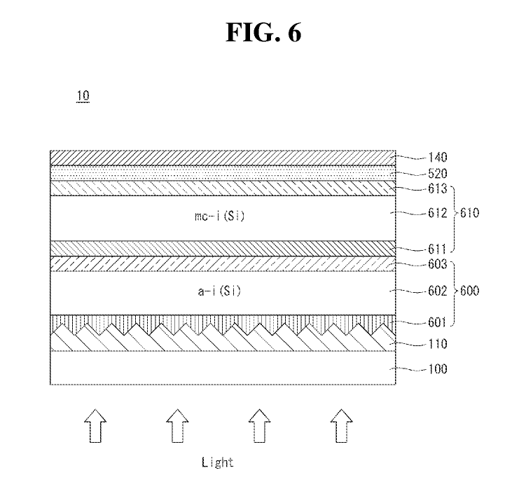

Further, the solar cell 10 according to the embodiment of the invention, as shown in FIG. 6, may include a first photoelectric conversion unit 600 formed of amorphous silicon and a second photoelectric conversion unit 610 formed of microcrystalline silicon (mc-Si).

The first photoelectric conversion unit 600 may include a first p-type semiconductor layer 601 formed of amorphous silicon, a first n-type semiconductor layer 603 formed of amorphous silicon, and a first i-type semiconductor layer 602 formed of amorphous silicon. The second photoelectric conversion unit 610 may include a second p-type semiconductor layer 611 formed of microcrystalline silicon, a second n-type semiconductor layer 613 formed of microcrystalline silicon, and a second i-type semiconductor layer 612 formed of microcrystalline silicon.

The second photoelectric conversion unit 610 formed of microcrystalline silicon has intermediate properties between crystalline silicon and amorphous silicon. Thus, the second photoelectric conversion unit 610 may have a bandgap voltage lower than that of the first photoelectric conversion unit 600.

The first photoelectric conversion unit 600 may absorb light of a short wavelength band to produce electric power, and the second photoelectric conversion unit 610 may absorb light of a long wavelength band to produce electric power.

Accordingly, as shown in FIG. 6, in the solar cell 10 including the first photoelectric conversion unit 600 formed of amorphous silicon and the second photoelectric conversion unit 610 formed of microcrystalline silicon, a light absorption band may widen, and thus the photoelectric conversion efficiency may be improved.

Further, a thickness of the second i-type semiconductor layer 612 may be greater than a thickness of the first i-type semiconductor layer 602, so as to sufficiently absorb the light of the long wavelength band.

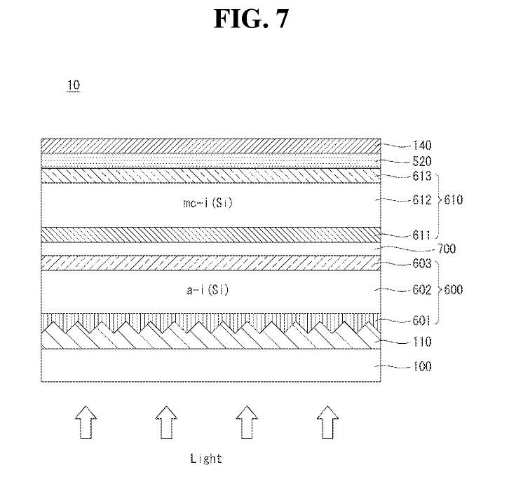

Further, the solar cell 10 according to the embodiment of the invention, as shown in FIG. 7, may further include a transparent electrode layer 700 disposed between the first photoelectric conversion unit 600 formed of amorphous silicon and the second photoelectric conversion unit 610 formed of microcrystalline silicon. The transparent electrode layer 700 may reduce an electrical resistance in a region between the first photoelectric conversion unit 600 and the second photoelectric conversion unit 610 to increase the photoelectric conversion efficiency. Further, the transparent electrode layer 700 may reduce the thickness of the first i-type semiconductor layer 602 to improve a stability efficiency.

After an i-type semiconductor layer is manufactured, the efficiency of the i-type semiconductor layer may be reduced during a predetermined incident period of light. For example, during the predetermined incident period of light, the efficiency of the i-type semiconductor layer may be reduced to about 80% to 85% of an initial efficiency measured immediately after the i-type semiconductor layer is manufactured.

Afterwards, a reduction amount of the efficiency of the i-type semiconductor layer is saturated, and the efficiency of the i-type semiconductor layer reaches a uniform efficiency. The uniform efficiency is referred to as a stability efficiency.

The characteristic in which the efficiency of the i-type semiconductor layer falls from the initial efficiency to the stability efficiency may deepen as a thickness of the i-type semiconductor layer increases. In other words, as the thickness of the i-type semiconductor layer decreases, the stability efficiency may increase. However, if the thickness of the i-type semiconductor layer excessively decreases, a light absorptance of the i-type semiconductor layer may be reduced. Hence, the efficiency of the solar cell may be reduced.

On the other hand, as shown in FIG. 7, if the transparent electrode layer 700 is positioned between the first and second photoelectric conversion units 600 and 610, the transparent electrode layer 700 may again reflect a portion of light transmitted by the first photoelectric conversion unit 600, and thus the light may be absorbed in the first photoelectric conversion unit 600. Hence, even if the thickness of the first i-type semiconductor layer 602 of the first photoelectric conversion unit 600 decreases, a reduction in the efficiency of the solar cell 10 may be prevented or reduced. Further, the stability efficiency may be improved.

The transparent electrode layer 700 may be formed of a material with a low light absorptance capable of reflecting a portion of light transmitted by the first photoelectric conversion unit 600 and sufficiently transmitting light of a long wavelength band. Preferably, the transparent electrode layer 700 may be formed of, for example, ZnO, SiOx, and ITO in consideration of a light absorptance and the manufacturing cost. The formation material of the transparent electrode layer 700, such as ZnO, SiOx, and ITO, may have substantially transparent properties. However, because the formation material of the transparent electrode layer 700 has really a predetermined light reflectance, the transparent electrode layer 700 may reflect a portion of light transmitted by the first photoelectric conversion unit 600.

The transparent electrode layer 700 disposed between the first and second photoelectric conversion units 600 and 610 may be referred to as an interlayer because of the above-described characteristic.

The embodiments of the invention may be applied to any solar cell including an amorphous silicon layer. For example, the embodiments of the invention may be applied to a single junction solar cell including an amorphous silicon layer, a hetero junction solar cell including an amorphous or microcrystalline silicon layer, and a multi-junction solar cell including an amorphous silicon layer.

Further, as shown in FIGS. 5, 6, and 7, the solar cell 10 according to the embodiments of the invention may have an uneven pattern on a light receiving surface. For example, a texturing process may be performed on the front surface 110 to form an uneven pattern. As above, when the uneven pattern is formed on the light receiving surface of the solar cell 10, an area of the light receiving surface may increase. Hence, the photoelectric conversion efficiency may be improved.

In addition, although FIGS. 5, 6, and 7 illustrate an example of forming the uneven pattern on only the front surface 110, the uneven pattern may be formed on the photoelectric conversion units 500, 510, 600, and/or 610.

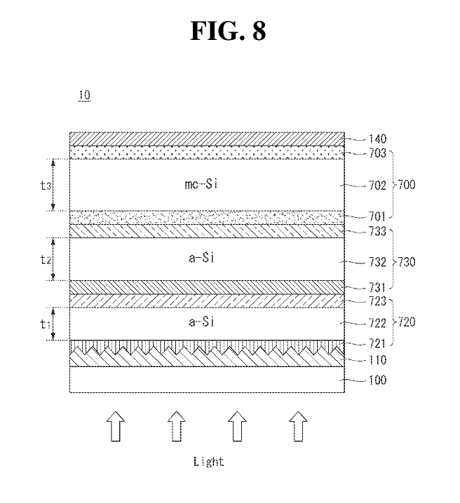

FIGS. 8 to 11 illustrate an example structure of a solar cell according to an embodiment of the invention. The solar cell shown in FIGS. 8 to 11 may be referred to as a pin-pin-pin type solar cell or a triple junction solar cell. In the following explanations, a further description of structures and components identical or equivalent to those illustrated in FIGS. 1 to 7 may be briefly made or may be entirely omitted.

As shown in FIG. 8, a solar cell 10 according to an embodiment of the invention may further include a first photoelectric conversion unit 720 including a first i-type semiconductor layer 722 formed of amorphous silicon, a second photoelectric conversion unit 730 including a second i-type semiconductor layer 732 formed of amorphous silicon, and a third photoelectric conversion unit 700 including a third i-type semiconductor layer 702 formed of microcrystalline silicon.

The first photoelectric conversion unit 720, the second photoelectric conversion unit 730, and the third photoelectric conversion unit 700 may be positioned on a light incident surface, i.e., the substrate 100 in the order named. More specifically, a first p-type semiconductor layer 721, a first i-type semiconductor layer 722, a first n-type semiconductor layer 723, a second p-type semiconductor layer 731, a second i-type semiconductor layer 732, a second n-type semiconductor layer 733, a third p-type semiconductor layer 701, a third i-type semiconductor layer 702, and a third n-type semiconductor layer 703 may be positioned on the substrate 100 in the order named.

The first photoelectric conversion unit 720 may be an amorphous silicon cell using amorphous silicon, for example, hydrogenated amorphous silicon (a-Si:H). The first photoelectric conversion unit 720 may absorb light of s short wavelength band to produce power.

The second photoelectric conversion unit 730 may be an amorphous silicon cell using amorphous silicon, for example, hydrogenated amorphous silicon (a-Si:H). The second photoelectric conversion unit 730 may absorb light of s middle wavelength band between the short wavelength band and a long wavelength band to produce electric power.

The third photoelectric conversion unit 700 may be a silicon cell using microcrystalline silicon, for example, hydrogenated microcrystalline silicon (mc-Si:H). The third photoelectric conversion unit 700 may absorb light of the long wavelength band to produce electric power.

Because each of the first, second, and third photoelectric conversion units 710, 720, and 700 absorbs light of different wavelength bands to produce electric power, the efficiency of the above-described triple junction solar cell 10 is at a sufficiently high level.

A thickness t3 of the third i-type semiconductor layer 702 may be greater than a thickness t2 of the second i-type semiconductor layer 732, and the thickness t2 of the second i-type semiconductor layer 732 may be greater than a thickness t1 of the first i-type semiconductor layer 722.

In the triple junction solar cell 10 shown in FIG. 8, a density of Si—Si bonds in at least one of the first i-type semiconductor layer 722 and the second i-type semiconductor layer 732 may be approximately 7.48×10²²/cm³ to 9.4×10²²/cm³, preferably, 7.8×10²²/cm³ to 9.0×10²²/cm³, though not required. The density of Si—Si bonds are as described above in detail.

Further, a density of Si—Si bonds in at least one of the first p-type semiconductor layer 721, the first n-type semiconductor layer 723, the second p-type semiconductor layer 731, and the second n-type semiconductor layer 733 may be approximately 7.48×10²²/cm³ to 9.4×10²²/cm³, preferably, 7.8×10²²/cm³ to 9.0×10²²/cm³, though not required.

The density of Si—Si bonds in at least one of the first p-type semiconductor layer 721, the first n-type semiconductor layer 723, the second p-type semiconductor layer 731, and the second n-type semiconductor layer 733 may be less than the density of Si—Si bonds in at least one of the first i-type semiconductor layer 722 and the second i-type semiconductor layer 732.

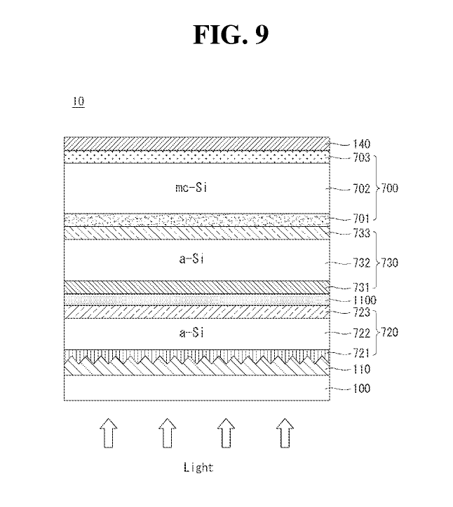

Next, as shown in FIG. 9, an interlayer 1100 may be positioned between the first photoelectric conversion unit 720 and the second photoelectric conversion unit 730. The interlayer 1100 may be referred to as a transparent electrode layer explained with reference to FIG. 7. The interlayer 1100 may reduce a thickness of the first i-type semiconductor layer 722 to thereby improve the stability efficiency of the solar cell 10.

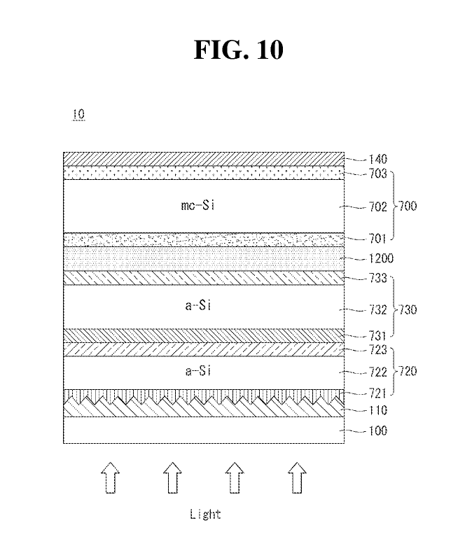

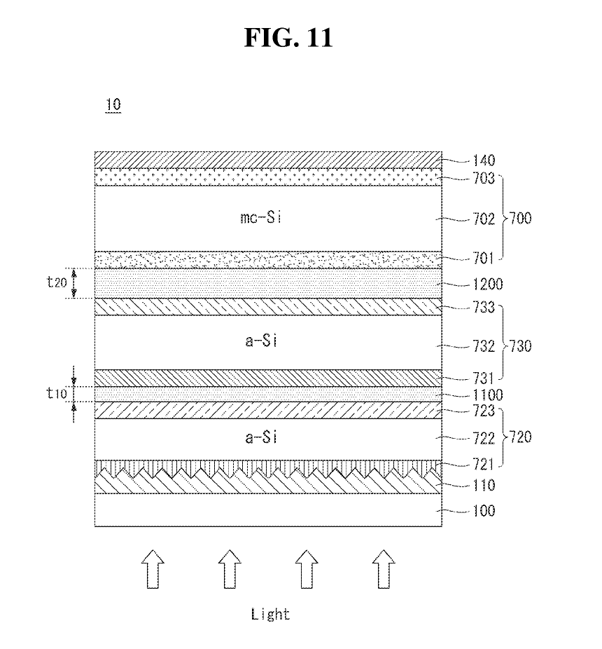

Further, as shown in FIG. 10, another interlayer 1200 may be positioned between the second photoelectric conversion unit 730 and the third photoelectric conversion unit 700.

Further, as shown in FIG. 11, a first interlayer 1100 may be positioned between the first and second photoelectric conversion units 720 and 730, and a second interlayer 1200 may be positioned between the second and third photoelectric conversion units 730 and 700.

In this case, it may be preferable, though not required, that an absorptance of the first i-type semiconductor layer 722 with respect to light of short wavelength band increases so as to further increase the efficiency of the solar cell 10. Therefore, it may be preferable, though not required, that the first interlayer 1100 efficiently reflects the light of a short wavelength band. For this, it may be preferable, though not required, that a refractive index of the first interlayer 1100 with respect to light of the short wavelength band is relatively large.

Further, it may be preferable, though not required, that an absorptance of the second i-type semiconductor layer 732 with respect to light of a middle or a long wavelength band increases so as to further increase the efficiency of the solar cell 10. For this, it may be preferable, though not required, that a refractive index of the second interlayer 1200 with respect to light of middle or long wavelength band is relatively large.

It is assumed that there are a first wavelength band and a second wavelength band longer than the first wavelength band.

It may be preferable, though not required, that a refractive index of the first interlayer 1100 is greater than a refractive index of the second interlayer 1200 at the first wavelength band, and the refractive index of the first interlayer 1100 is less than the refractive index of the second interlayer 1200 at the second wavelength band.

It may be preferable, though not required, that the refractive index of the second interlayer 1200 is equal to or greater than the refractive index of the first interlayer 1100, and also a thickness t20 of the second interlayer 1200 is greater than a thickness t10 of the first interlayer 1100.

In embodiments of the invention, reference to front or back, with respect to electrode, a surface of the substrate, or others is not limiting. For example, such a reference is for convenience of description since front or back is easily understood as examples of first or second side or surface of the electrode, the substrate or others.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

What is claimed is:

1. A solar cell, comprising:
a first electrode;
a second electrode; and
an amorphous silicon layer disposed between the first electrode and the second electrode,
wherein a density of Si—Si bonds in the amorphous silicon layer is 7.48×10²²/cm³ to 9.4×10²²/cm³.

2. The solar cell of claim 1, wherein the density of Si—Si bonds in the amorphous silicon layer is 7.8×10²²/cm³ to 9.0×10²²/cm³.

3. The solar cell of claim 1, wherein the density of Si—Si bonds in the amorphous silicon layer is greater than a density of Si—H bonds in the amorphous silicon layer.

4. The solar cell of claim 3, wherein the density of Si—H bonds in the amorphous silicon layer is greater than a density of dangling bonds.

5. The solar cell of claim 1, further comprising:
a substrate connected to the first electrode; and
a photoelectric conversion unit disposed between the first electrode and the second electrode that includes the amorphous silicon layer.

6. A solar cell, comprising:
a substrate;
a first electrode on the substrate;
a second electrode; and
a photoelectric conversion unit disposed between the first electrode and the second electrode, the photoelectric conversion unit including a p-type semiconductor layer formed of amorphous silicon, an intrinsic (i-type) semiconductor layer formed of amorphous silicon, and an n-type semiconductor layer formed of amorphous silicon,
wherein a density of Si—Si bonds in at least one of the p-type semiconductor layer, the i-type semiconductor layer, and the n-type semiconductor layer is 7.48×10²²/cm³ to 9.4×10²²/cm³.

7. The solar cell of claim 6, wherein the density of Si—Si bonds in at least one of the p-type semiconductor layer, the i-type semiconductor layer, and the n-type semiconductor layer is 7.8×10²²/cm³ to 9.0×10²²/cm³.

8. The solar cell of claim 6, wherein a density of Si—Si bonds in at least one of the p-type semiconductor layer and the n-type semiconductor layer is less than a density of Si—Si bonds in the i-type semiconductor layer.

9. A solar cell, comprising:
a substrate;
a first electrode on the substrate;
a second electrode;
a first photoelectric conversion unit disposed between the first electrode and the second electrode, the first photoelectric conversion unit including a first intrinsic (i-type) semiconductor layer formed of amorphous silicon, a density of Si—Si bonds in the first i-type semiconductor layer being 7.48×10²²/cm³ to 9.4×10²²/cm³; and
a second photoelectric conversion unit disposed between the first photoelectric conversion unit and the second electrode, the second photoelectric conversion unit including a second i-type semiconductor layer formed of microcrystalline silicon.

10. The solar cell of claim 9, wherein the density of Si—Si bonds in the first i-type semiconductor layer is 7.8×10²²/cm³ to 9.0×10²²/cm³.

11. The solar cell of claim 9, wherein the first photoelectric conversion unit includes a first p-type semiconductor layer formed of amorphous silicon and a first n-type semiconductor layer formed of amorphous silicon, and
the second photoelectric conversion unit includes a second p-type semiconductor layer formed of microcrystalline silicon and a second n-type semiconductor layer formed of microcrystalline silicon.

12. The solar cell of claim 11, wherein a density of Si—Si bonds in at least one of the first p-type semiconductor layer and the first n-type semiconductor layer is less than the density of Si—Si bonds in the first i-type semiconductor layer.

13. The solar cell of claim 9, wherein a thickness of the second i-type semiconductor layer is greater than a thickness of the first i-type semiconductor layer.

14. The solar cell of claim 9, further comprising an interlayer disposed between the first photoelectric conversion unit and the second photoelectric conversion unit.

15. A solar cell, comprising:
a substrate;
a first electrode on the substrate;
a second electrode;
a first photoelectric conversion unit disposed between the first electrode and the second electrode, the first photoelectric conversion unit including a first intrinsic (i-type) semiconductor layer formed of amorphous silicon;
a second photoelectric conversion unit disposed between the first photoelectric conversion unit and the second electrode, the second photoelectric conversion unit including a second i-type semiconductor layer formed of amorphous silicon; and
a third photoelectric conversion unit disposed between the second photoelectric conversion unit and the second electrode, the third photoelectric conversion unit including a third i-type semiconductor layer formed of microcrystalline silicon,
wherein a density of Si—Si bonds in at least one of the first i-type semiconductor layer and the second i-type semiconductor layer is 7.48×10²²/cm³ to 9.4×10²²/cm³.

16. The solar cell of claim 15, wherein the density of Si—Si bonds in at least one of the first i-type semiconductor layer and the second i-type semiconductor layer is 7.8×10²²/cm³ to 9.0×10²²/cm³.

17. The solar cell of claim 15, wherein the first photoelectric conversion unit includes a first p-type semiconductor layer formed of amorphous silicon and a first n-type semiconductor layer formed of amorphous silicon,
the second photoelectric conversion unit includes a second p-type semiconductor layer formed of amorphous silicon and a second n-type semiconductor layer formed of amorphous silicon, and
the third photoelectric conversion unit includes a third p-type semiconductor layer formed of microcrystalline silicon and a third n-type semiconductor layer formed of microcrystalline silicon.

18. The solar cell of claim 17, wherein a density of Si—Si bonds in at least one of the first p-type semiconductor layer, the first n-type semiconductor layer, the second p-type semiconductor layer, and the second n-type semiconductor layer is less than the density of Si—Si bonds in each of the first i-type semiconductor layer and the second i-type semiconductor layer.
